(19) United States
(12) Patent Application Publication
(10) Pub. No.: US 2009/0153029 A1
(43) Pub. Date: Jun. 18, 2009

(54) LIGHT EMITTING DIODES, INCLUDING HIGH-EFFICIENCY OUTCOUPLING OLED UTILIZING TWO-DIMENSIONAL GRATING

(76) Inventor: Viktor B. Khalfin, Highstown, NJ (US)

Correspondence Address: FOLEY & LARDNER LLP, 150 EAST GILMAN STREET, P.O. BOX 1497, MADISON, WI, 53701-1497, US

(21) Appl. No.: 11/954,957

(22) Filed: Dec. 12, 2007

(51) Int. Cl. H01J 1/62; F21V 9/16; F21V 5/00; H01L 31/0232

(52) U.S. Cl. 313/504; 362/84; 257/98; 257/E31.127

(57) ABSTRACT

The present disclosure relates to increasing the external efficiency of light emitting diodes, and specifically to increasing the outcoupling of light from an organic light emitting diode utilizing a diffraction grating.

### BACKGROUND

1. Field

The present disclosure relates generally to light emitting diodes, including increasing an outcoupling of light from an organic light emitting diode utilizing a diffraction grating.

2. Background Information

Typically an organic light-emitting diode (OLED) is a type of light-emitting diode (LED) in which the emissive layer often comprises a thin-film of certain organic compounds. The emissive electroluminescent layer can include a polymeric substance that allows the deposition of suitable organic compounds, for example, in rows and columns on a flat carrier by using a simple “printing” method to create a matrix of pixels which can emit different colored light. Such systems can be used in television screens, computer displays, portable system screens, advertising and information, and indication applications etc. OLEDs can also be used in light sources for general space illumination. OLEDs typically emit less light per area than inorganic solid-state based LEDs which are usually designed for use as point light sources.

One of the benefits of an OLED display over the traditional LCD displays is that OLEDs typically do not require a backlight to function. This means that they often draw far less power and, when powered from a battery, can operate longer on the same charge. It is also known that OLED-based display devices can often be more effectively manufactured than liquid-crystal and plasma displays.

Prior to standardization, OLED technology was also referred to as Organic Electro-Luminescence (OEL).

As illustrated by FIG. 1, an Organic LED 100 typically includes an organic layer (or layers) 130 in addition to the substrate 110, anode 120 and cathode 140. When multiple organic layers are used, two of the layers may typically include an Emissive layer and a Conductive layer. Both these layers are frequently made up of organic molecules or polymers. These selected compounds are typically labeled as Organic Semiconductors and certain conductivity levels are shown by these compounds ranging between those of insulators and conductors.

OLEDs often emit light in a similar manner to LEDs, through a process called electrophosphorescence. As the voltage is applied across the OLED such that the anode has a positive voltage with respect to the cathode, a current starts flowing through the device. The direction of (conventional) current flow is from anode to cathode, hence electrons flow from cathode to anode. Thus, in the case where there are two organic layers, one conductive and one emissive, the cathode gives electrons to the emissive layer and the anode withdraws electrons from the conductive layer, in essence, the process creates holes in the conductive layer).

Hence, after a short time period, the emissive layer will typically become rich in negatively charged electrons while the conductive layer has an increased concentration of positively charged holes. Due to natural affinity for unlike charges, these two are attracted to each other. It is to be noted here that in organic semiconductors, in contrast to the inorganic semiconductors, the hole mobility is often greater than the mobility of electrons. Hence, as the two charges move towards each other, it is more likely that their recombination will occur in the emissive layer. Due to this recombination, there is an accompanying drop in the energy levels of the electrons and this drop is characterized by the emission of radiation with a frequency lying in the visible region, viz. light is produced. That is the reason behind this layer being called the emissive layer.

Typically, the device will not work when the anode is put at a negative potential, with respect to the cathode. This is because in this condition, the anode will pull holes towards itself and the cathode will pull the electrons. Therefore, the electrons and holes are moving away from each other and will not recombine.

The external efficiency of current organic light emitting diodes (OLEDs) is frequently low. Most of the radiated light 150 is trapped by internal reflection in the organic layer and the anode layer, which have often higher indexes of refraction than the substrate and the surrounding air. As shown in FIG. 1, only radiated light 150 emitted nearly perpendicular to the layers can easily escape (paths 191 & 192). Radiated light 150 emitted away from perpendicular is not likely to escape. Depending on the direction of emission, radiated light 150 may be trapped at the substrate-air interface (path 193), at the anode-substrate interface (path 194) or at the organic-anode interface (path 195). Such radiated light 150 trapped at the organic-anode interface may result in light being confined within the organic layer 130 itself (referred to herein as a waveguide mode) and/or result in light being trapped at an organic-electrode interface (referred to herein as a surface plasmon). It has been estimated that about 50% of the emitted light of an OLED may be trapped as a surface plasmon. Light that does not escape is ultimately absorbed within the structure.

### BRIEF DESCRIPTION OF THE DRAWINGS

FIG. 1 is a partially schematic diagram illustrating an embodiment of an organic light emitting diode in accordance with the prior art;

FIG. 2 is a partially schematic diagram illustrating an embodiment of an organic light emitting diode in accordance with an embodiment of the invention;

FIG. 3 is a partially schematic diagram illustrating an embodiment of an organic light emitting diode in accordance with an embodiment of the invention;

FIG. 4A is a partially schematic diagram illustrating an embodiment of diffraction grating patterns in accordance with an embodiment of the invention;

FIG. 4B is a partially schematic diagram illustrating an embodiment of diffraction grating patterns in accordance with an embodiment of the invention;

FIG. 4C is a partially schematic diagram illustrating an embodiment of diffraction grating patterns in accordance with an embodiment of the invention;

FIG. 5 is a partially schematic diagram illustrating an embodiment of diffraction grating patterns in accordance with an embodiment of the invention;

FIG. 6 is a graph illustrating the relationship between outcoupling and grating period in accordance with an embodiment of the invention; and

FIG. 7 is a block diagram illustrating an embodiment of an apparatus and a system in accordance with an embodiment of the invention.

### DETAILED DESCRIPTION

In the following detailed description, numerous details are set forth in order to provide a thorough understanding of claimed subject matter. However, it will be understood by those skilled in the art that claimed subject matter may be practiced without these specific details. In other instances, well-known methods, procedures, components, and circuits have not been described in detail so as to not obscure claimed subject matter.

In the following detailed description, reference is made to the accompanying drawings which form a part hereof, and in which is shown by way of illustration embodiments in which the invention may be practiced. It is to be understood that other embodiments may be utilized and structural or logical changes may be made without departing from the scope of claimed subject matter. Therefore, the following detailed description is not to be taken in a limiting sense, and the scope of embodiments in accordance with claimed subject matter and equivalents thereof.

Various operations may be described as multiple discrete operations in turn, in a manner that may be helpful in understanding claimed subject matter; however, the order of description should not be construed to imply that these operations are order dependent.

For the purposes of the description, a phrase in the form “A/B” means A or B. For the purposes of the description, a phrase in the form “A and/or B” means “(A), (B), or (A and B)”. For the purposes of the description, a phrase in the form “at least one of A, B, and C” means “(A), (B), (C), (A and B), (A and C), (B and C), or (A, B and C)”. For the purposes of the description, a phrase in the form “(A)B” means “(B) or (AB)” that is, A is an optional element.

For purposes of the description, a phrase in the form “below”, “above”, “to the right of”, etc. are relative terms and do not require that claimed subject matter be used in any absolute orientation.

For ease of understanding, the description will be in large part presented in the context of display technology; however, claimed subject matter is not so limited, and may be practiced to provide more relevant solutions to a variety of illumination needs. Reference in the specification to a processing and/or digital “device” and/or “appliance” means that a particular feature, structure, or characteristic, namely device operable connectivity, such as the ability for the device to be execute or process instructions and/or programmability, such as the ability for the device to be configured to perform designated functions, is included in at least one embodiment of the digital device as used herein. Accordingly in one embodiment, digital devices may include general and/or special purpose computing devices, connected personal computers, network printers, network attached storage devices, voice over internet protocol devices, security cameras, baby cameras, media adapters, entertainment personal computers, and/or other networked devices suitably configured for practicing the present invention in accordance with at least one implementation; however these are merely a few examples of processing devices to which claimed subject matter is not limited.

The description may use the phrases “in an embodiment,” or “in embodiments,” which may each refer to one or more of the same or different embodiments. Furthermore, the terms “comprising,” “including,” “having,” and the like, as used with respect to embodiments of the present invention, are synonymous.

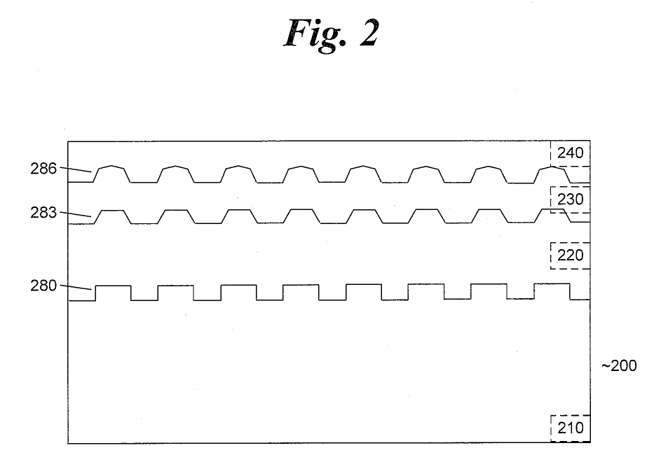

FIG. 2 is a partially schematic diagram illustrating an embodiment of an organic light emitting diode (OLED) 200 in accordance with claimed subject matter. The OLED may include a plurality of layers, such as, for example, a substrate 210, an anode layer 220, an organic layer 230, and a cathode layer 240. FIG. 2 illustrates a bottom-emitter OLED, as light is emitted through the substrate. Other embodiments, of claimed subject matter may include other forms of OLEDs (not shown), such as, for example, top-emitter OLEDS (where light is emitted though a cover), a transparent OLED (where it is possible to emit light through both the top and bottom of the device), a foldable OLED (where substrates may include a very flexible metallic foil or plastics), passive-matrix OLEDs (where strips of the cathode, anode, and organic layers may be used), or active-matrix OLEDs (where often a thin film transistor array is overlayed onto the typical OLED layers), etc. In one embodiment, the organic layer(s) of the OLED may be between 100 to 500 nanometers (nm) thick.

In one embodiment the substrate 210 may include glass, plastic, a thin film, ceramic, a semi-conductor, or a foil. Here, this substrate may be substantially optically clear, although in other embodiments an opaque material may be used. In one embodiment the substrate may be approximately 1 millimeter (mm) thick and include an index of refraction of 1.45. In one embodiment, the substrate may be capable of supporting at least one of the other layers of the LED.

In one embodiment, the anode 220 may remove electrons (i.e. adds electron “holes”) when current flows through the device. For example, the anode 220 may remove electrons from organic layer 220, such as for example, a conductive layer portion of organic layer 220 creating electron holes within the conductive layer portion. In the case of the bottom-emitting OLED illustrated in FIG. 2, the anode may be substantially transparent. In some embodiments, transparent anode materials may include indium-tin oxide (ITO), indium-zinc oxide (IZO) and/or tin oxide, but other metal oxides may be used, such as, for example, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, may be used as the anode in various embodiments. In other embodiments, the transmissive characteristics of the anode may be immaterial and any conductive material may be used, transparent, opaque or reflective. Example conductors for these embodiments may include, but are not limited to, gold, iridium, molybdenum, palladium, and platinum. In one embodiment, the anode layer may be approximately 200 nanometers thick, and have an index of refraction of 2.

In one embodiment, the organic layer 220 may include conductive and emissive layers, and, in some embodiments, a third or fourth organic layer. For this reason, the organic layer is sometimes referred to as the organic stack. These organic layers are often made of organic molecules or polymers. In one embodiment, the organic layer may be approximately 100-500 nanometers thick, and have an index of refraction of 1.72.

In one embodiment, the conducting layer may be made of organic plastic molecules that transport “holes” created by the anode. One conducting polymer used in OLEDs is polyaniline, although that is merely one non-limiting embodiment of claimed subject matter. The following are a few illustrative examples of possible materials that may be used various embodiments of claimed subject matter: aromatic tertiary amines, polycyclic aromatic compounds, and polymeric hole-transporting materials.

In one embodiment, the emissive layer may be made of organic plastic molecules (different ones from the conducting layer) that accumulates electrons based on the voltage applied across the OLED. Electroluminescence is produced based on these accumulated electrons as a result of electron-hole pair recombination. One polymer used in some embodiments of the emissive layer is polyfluorene, although that is merely one non-limiting embodiment of claimed subject matter.

The emissive layer or light-emitting layer can be comprised, in one embodiment, of a single material. In other embodiments, such a light emitting layer may consist of a host material doped with a guest compound or compounds where light emission comes primarily from the dopant and can be of any color. Various dopants may be combined to produce colors. In one embodiment, this technique may be used to produce a white OLED. In one embodiment, dopants may be chosen from highly florescent dyes. In other embodiments, dopants may include phosphorescent compounds. The following are a few illustrative examples of possible materials that may be used as host materials in various embodiments of claimed subject matter: tris(8-quinolinolato)aluminum (III) (Alq3), metal complexes of 8-hydroxyquinoline (oxine) and similar derivatives, derivatives of anthracene, distyrylarylene derivatives, benzazole derivatives, or carbazole derivatives.

In various embodiments, the conducting layer and emissive layer may be combined into a single layer. In versions of these embodiments, the emissive dopants may be added to a hole-transporting material.

In other embodiments, the organic layer 230 may also include additional organic layers. In one embodiment, a hole-injecting layer may be added below or as part of the conductive layer. The hole-injecting layer, in one embodiment, may serve to improve the film formation property of subsequent organic layers and to facilitate injection of holes into the conductive layer. In another embodiment, an electron-transporting layer may be included above the emissive layer. The electron-transporting layer may, in one embodiment, help to inject and/or transport electrons.

In one embodiment, the cathode 240 may provide electrons (i.e. removes electron “holes”) when current flows through the device. In the case of the bottom-emitting OLED illustrated in FIG. 2, the cathode may be substantially opaque. However, in other embodiments, it may be desirable to utilize a transparent cathode. In some embodiments, cathode materials may include a lithium fluoride (LiF) layer backed by an aluminum (Al) layer, Magnesium/Silver (Mg:Ag), metal salts, or other transparent cathodes.

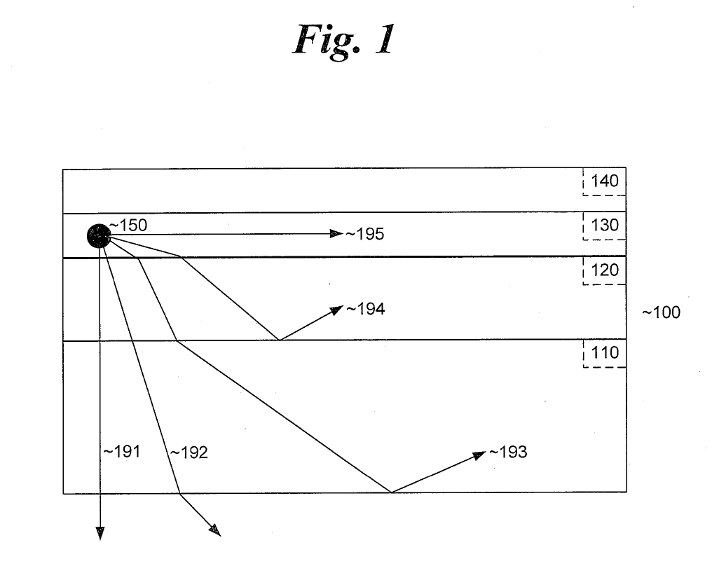

As illustrated by FIG. 1, with a conventional OLED a large portion of the light emitted by the organic layer does not leave the LED. A technique in accordance with selected embodiments of the invention is to scatter or direct light emitted in an unfavorable direction to a more favorable direction. Such a favorable direction allows the light to escape the LED structure. For example, in certain embodiments, techniques can be used to scatter, diffract, and/or redirect at least a portion of the light that would not escape in conventional OLEDs (e.g. paths 193, 194, & 195 shown in FIG. 1) to a direction that allows the light to escape. For example, in selected embodiments a diffraction grating can be used to scatter, diffract, and/or redirect at least a portion of the emitted light.

Referring to FIG. 2, in one embodiment, a diffraction grating 280 may be formed on the substrate 210. In one embodiment, this diffraction grating may comprise a relief grating. This grating may be formed on the substrate-anode boundary. As the light reflects off or transmits through the diffraction grating it is likely to be outcoupled and therefore more likely to be emitted from the LED as opposed to being trapped within the LED and eventually absorbed. As used herein, the term “outcoupling” may mean a measure of the quantity of light emitted from a device as compared to the total available light.

In one embodiment, the substrate's diffraction grating may be transferred to the other layers of the LED. As a layer is added to the substrate, the prior diffraction grating may cause a new diffraction grating to be created on the newest top layer. For example a diffraction grating on the anode-organic layer boundary (anode's diffraction grating 283) may be derived from the substrate's diffraction grating 280. For example, a diffraction grating on the anode-organic layer boundary (anode's diffraction grating 283) may be formed as the anode layer is placed or formed over the substrate layer using various deposition processes. Subsequently, in one embodiment, a diffraction grating may be formed on the organic-cathode boundary (emissive layer's diffraction grating 286). This grating may also be derived from the substrate's grating via the anode's grating.

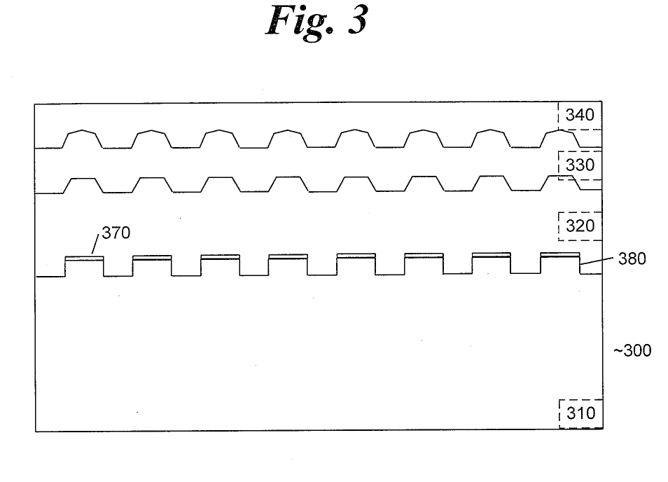

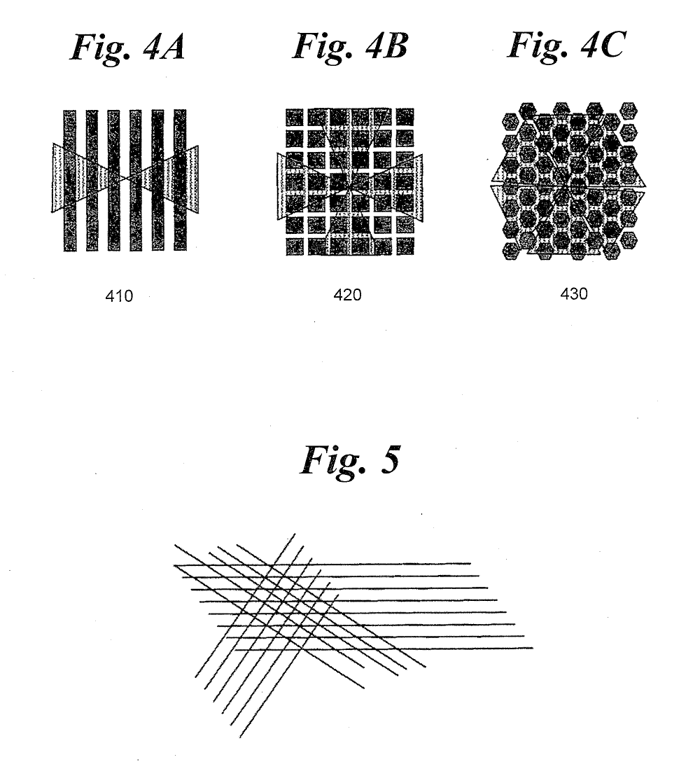

In one embodiment, the diffraction grating may include a pattern with grooves in one-dimension such as that shown in FIG. 4A, 410. For an emitter at the apex of the triangles, only photons emitted in the direction of the shaded triangles will scatter in the correct direction to outcouple. Additionally or alternatively, grating 410 may comprise a series of elements (e.g., grooves and/or surfaces) distributed in an array, where the series of elements may be rectangular, hexagonal, ovoid, and/or the like in shape. In one embodiment, such as that shown in FIG. 4B, a double grating 420 may be used, which includes elements (e.g., grooves and/or surfaces) distributed in a rectangular or more generally a quadrilateral characteristic. Such a quadrilateral grating may outcouple photons emitted in the directions represented by the four shaded triangles. Additionally or alternatively, double grating 420 may comprise a series of elements (e.g., grooves and/or surfaces) distributed in an array, where the series of elements may be square, hexagonal, spherical, and/or the like in shape. In another embodiment, such as that shown in FIG. 4C, a triple grating 430 may be used. This grating may include a hexagonal pattern or characteristic. In the illustrated embodiment, a grating pattern of three series of lines inclined at 120 degree angles may be used. Once again, this hexagonal grating may outcouple photons emitted in the directions represented by the six shaded triangles. It can be seen that using the triple grating pattern, light emitted in almost any direction may be outcoupled from the LED. Additionally or alternatively, triple grating 430 may comprise a series of elements (e.g., grooves and/or surfaces) distributed in an array, where the series of elements may be square, hexagonal, spherical, and/or the like in shape. In other embodiments, a grating (e.g., an n-grating) can include an array configured to outcouple photons in more or fewer directions. In still other embodiments, as shown in FIG. 5, a non-symmetrical diffraction grating 510 pattern may be used.

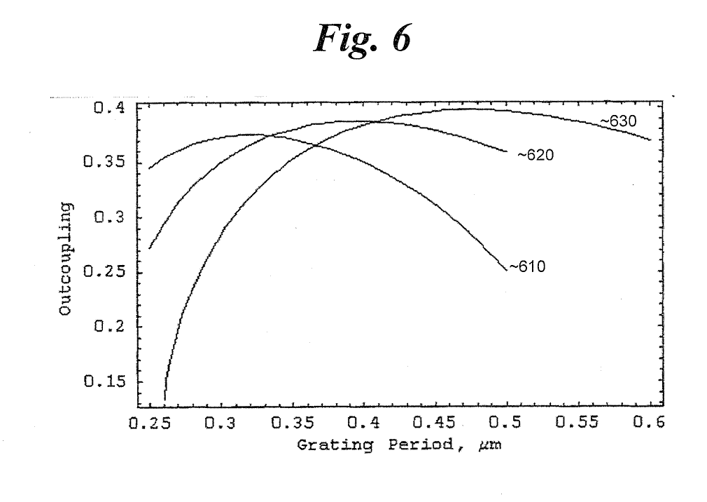

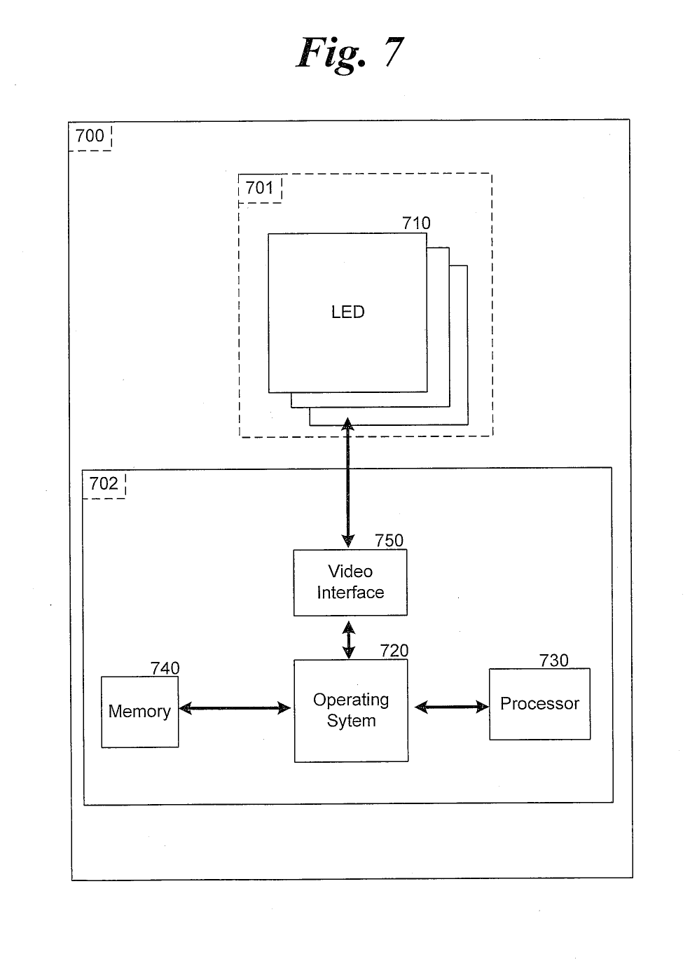

FIG. 6 illustrates, in one embodiment, a plot of a grating period against outcoupling for different wavelengths in accordance with a selected embodiment. Such a plot of a grating period against outcoupling may be utilized in the selection of the period of the diffraction grating grooves. As used herein, the term “grating period” may refer to the spacing from a location of one element (e.g., groove and/or surface) to the location of an adjacent element (e.g., groove and/or surface), such as for example, the spacing from a center of one grating to the center of an adjacent grating. Additionally, as used herein, the term “outcoupling” may mean a measure of the quantity of light emitted from the device as compared to the total available light. Three wavelengths are considered. Plot 610 illustrates one embodiment of the outcoupling of the 470 nm wavelength. Plot 620 illustrates one embodiment of the outcoupling of the 560 nm wavelength. Plot 630 illustrates one embodiment of the outcoupling of the 660 nm wavelength. These are, respectively, the short, medium, and long wavelengths of light emitted from the emissive layer (e.g., an emissive layer that includes Alq3). It is understood that other organic layers may generate other outcoupling patterns.

In one embodiment, the period of the diffraction grating grooves may be selected to be substantially 0.4 microns. As illustrated by FIG. 6, this period would outcouple the most amount of emitted light of the total of the three wavelengths combined from the emissive layer (e.g., an emissive layer that includes Alq3). In another embodiment, a different period corresponding to the spectrum of the emission agent and waveguide may be used. It is also understood that the period may not be consistent throughout individual diffraction gratings, an LED, or a total display. It is also understood that when an LED includes multiple layers with different diffraction gratings, each layer's diffraction grating may include different periods.

An additional consideration in selected embodiments is that an emitted photon be scattered before it is absorbed. This may dictate the coupling strength of the light to the grating. In one embodiment, where an aluminum cathode is used, the photon may be absorbed within 20 wavelengths. Accordingly, in one particular embodiment, light and grating may be strongly coupled by placing a diffraction grating at the emissive layer-cathode boundary. For example, in one embodiment, the coupling strength of the organic-cathode boundary may be 10 times higher in comparison with the other grating patterns due to the large difference between the dielectric constants of the cathode and organic layers.

Also, in one embodiment, a diffraction grating may be created with a grating period sufficiently sized to allow a photon to interact with the grating before it is absorbed. In one embodiment, the substrate's diffraction grating includes a grating period of between 10 to 20 polariton wavelengths. As discussed above, in other embodiments gratings can have other grating periods.

In one embodiment, the diffraction grating system may increase the amount of light emitted externally from the LED by a factor of threefold as compared to a LED without the diffraction grating system. In another embodiment, the diffraction grating system can have other efficiencies. For example, in certain embodiments the diffraction grating system can have an efficiency of 45%-50% as compared to a 15% efficiency associated with some conventional LEDs

FIG. 3 is a partially schematic diagram illustrating an embodiment of an organic light emitting diode in accordance another embodiment of the invention. Elements 300, 310, 320, 330, 340, and 380 are analogous to elements 200, 210, 220, 230, 240, and 280 of FIG. 2 described above. In FIG. 3, a diffraction grating 380 similar to the one illustrated in FIG. 2 and described above is present. In addition, metal strips 370 may be added along the ridges diffraction grating at the substrate-anode boundary. In one embodiment the strips may be very thin, so as not to induce additional loses. In a specific embodiment, the strips may be approximately 5 nanometers thick. In one embodiment, the strips may comprise silver (Ag). However, these are merely a few non-limiting examples of metal strips that may be used to form diffraction gratings and claimed subject matter is not so limited.

As discussed above, radiated light may be trapped at an organic-anode interface resulting in light being confined within the organic layer itself (referred to herein as a waveguide mode) and/or resulting in light being trapped at an organic-electrode interface (referred to herein as a surface plasmon). In one embodiment, the waveguide modes and surface plasmons may be radiated in an isotropic fashion in the plane of the diffraction grating. The diffraction grating of FIG. 2 may, in one embodiment, output surface plasmons and transverse-magnetic (TM) waveguide modes because for these modes the intensity is high near the metal surface (viz. the cathode-organic boundary). As used herein, the term “transverse-magnetic” may refer to a waveguide mode that has no magnetic field in a direction of propagation. Unfortunately, in some cases the transverse-electric (TE) waveguide modes have a low intensity near the metal surface. As used herein, the term “transverse-electric” may refer to a waveguide mode that has no electric field in a direction of propagation. So, the diffractive grating will not output (TE) modes efficiently. In one embodiment, adding the metal strips 370 of FIG. 3 may increase the outcoupling of the (TE) modes of the waveguide at the anode-substrate boundary.

In one embodiment, a technique for manufacturing an organic LED as described above may include the following actions. A substrate may be obtained. The substrate may, in one embodiment, have a diffraction grating etched into it. It is understood that other embodiments may exist in which etching is not used to produce the diffraction grating upon the substrate. For example, in one embodiment, the diffraction grating may be grown or applied to the substrate.

In one embodiment, a hexagonal array of polystyrene spheres (not shown), suitable for use in forming a triple grating similar to that shown at 430 in FIG. 4C may be created. For example, such a hexagonal array of polystyrene spheres may comprise a single layer (or monolayer) of polystyrene spheres. This array may then be used to etch the substrate. In another embodiment, heavy ion implantation, such as for example soaking a photographically developed glass plate in a salt, may be used to form the grating. From this a surface relief etching may be made.

The other layers of the LED may then be applied or added on top of the substrate. It is contemplated that in various embodiments the layers may be formed separately and added to the substrate individually or as a preformed group. In one embodiment, these layers may be applied in order to form an embodiment of the LED illustrated in FIG. 2. In another embodiment, the layers may be applied in order to form an embodiment of the LED illustrated in FIG. 3. In still other embodiments, the layers may be applied to form other LED structures. In selected embodiments, these layers may be applied in such a way as to allow the transfer of the substrate's diffractive grating onto the other layers. For example, each layer may be applied so as to create a new diffractive grating that is substantially derived from the substrate's diffractive grating.

In one embodiment, some of the layers may be applied using a technique known as or substantially similar to vacuum deposition or vacuum thermal evaporation (VTE). In one embodiment of vacuum deposition, a vacuum chamber, the organic molecules are gently heated (evaporated) and allowed to condense as thin films onto cooled substrates.

In another embodiment, some of the layers may be applied using a technique known as or substantially similar to organic vapor phase deposition (OVPD). In one embodiment of organic vapor phase deposition, in a low-pressure, hot-walled reactor chamber, a carrier gas transports evaporated organic molecules onto cooled substrates, where they condense into thin films. In some cases, using a carrier gas may increase the efficiency and reduces the cost of making OLEDs.

In yet another embodiment, some of the layers may be applied using a technique known as or substantially similar to splattering or inkjet printing. In one embodiment, splattering may include spraying the layers onto substrates just like inks are sprayed onto paper during printing. In some cases, inkjet technology may greatly reduce the cost of OLED manufacturing and allow OLEDs to be printed onto very large films for large displays like 80-inch TV screens or electronic billboards.

It is contemplated that one or more of these techniques may be used to make or manufacture an embodiment of the disclosed subject matter. In other embodiments other techniques may be used. It is also contemplated that the manufacture of these embodiments may be automated.

FIG. 7 is a block diagram illustrating an embodiment of an apparatus 710 and a system 700 in accordance with selected embodiments of the invention. In one embodiment, the system may include a display 701 and a processing device 702. In one embodiment, the display and processing device may be integrated, such as, for example in a media device, a mobile phone, or other small form factor device.

In one embodiment, the display 701 may include at least one LED similar to those discussed above with reference to FIGS. 2 & 3. In other embodiments the LEDs may include other forms of LEDs which are not bottom-emitting LEDs but include some of the features of the LEDs described above.

In one embodiment, the processing device 702 may include an operating system 720, a video interface 750, a processor 730, and a memory 740. In one embodiment, the operating system may be capable of facilitating the use of the system and generating a user interface. The processor 730 may be capable of, in one embodiment, executing or running the operating system. The memory 740 may be capable of, in one embodiment, storing the operating system. The video interface 750 may, in one embodiment, be capable of facilitating the display of the user interface and interacting with the display 701. In one embodiment, the video interface may be included within the display.

The techniques described herein are not limited to any particular hardware or software configuration; they may find applicability in any computing or processing environment. The techniques may be implemented in hardware, software, firmware or a combination thereof. The techniques may be implemented in programs executing on programmable machines such as mobile or stationary computers, personal digital assistants, and similar devices that each include a processor, a storage medium readable or accessible by the processor (including volatile and non-volatile memory and/or storage elements), at least one input device, and one or more output devices. Program code is applied to the data entered using the input device to perform the functions described and to generate output information. The output information may be applied to one or more output devices.

Each program may be implemented in a high level procedural or object oriented programming language to communicate with a processing system. However, programs may be implemented in assembly or machine language, if desired. In any case, the language may be compiled or interpreted.

Each such program may be stored on a storage medium or device, e.g. compact disk read only memory (CD-ROM), digital versatile disk (DVD), hard disk, firmware, non-volatile memory, magnetic disk or similar medium or device, that is readable by a general or special purpose programmable machine for configuring and operating the machine when the storage medium or device is read by the computer to perform the procedures described herein. The system may also be considered to be implemented as a machine-readable or accessible storage medium, configured with a program, where the storage medium so configured causes a machine to operate in a specific manner. Other embodiments are within the scope of the following claims.

While certain features of claimed subject matter have been illustrated and described herein, many modifications, substitutions, changes, and equivalents will now occur to those skilled in the art. It is, therefore, to be understood that the appended claims are intended to cover all such modifications and changes that fall within the true spirit of claimed subject matter.

The following is claimed:

1. An apparatus comprising:
a light emitting diode (LED) including:
an emissive layer capable of emitting light,
a substrate having a diffraction grating, wherein the substrate's diffraction grating is capable of at least in part directing the scattering of light emitted by the emissive layer, and
a layer of metal strips disposed along the ridges of the substrate diffraction grating.

2. The apparatus of claim 1, wherein the light emitting diode includes an organic light emitting diode.

3. The apparatus of claim 1, the substrate's diffractive grating includes a transmission diffractive grating.

4. The apparatus of claim 1, further including an anode having a diffraction grating derived, at least in part, from the substrate's diffractive grating and wherein the anode's diffraction grating is capable of at least in part directing the scattering of light emitted by the emissive layer, and
wherein the anode is disposed substantially between the emissive layer and the substrate.

5. The apparatus of claim 4, wherein the anode includes a layer of indium tin oxide (ITO);
wherein the emissive layer includes a layer of Tris-8-Hydroxyquinoline Aluminum (Alq₃);
wherein the layer of metal strips includes silver; and
wherein the substrate includes glass.

6. The apparatus of claim 4, further including a cathode, wherein the emissive layer is disposed substantially between the cathode and the anode, and the cathode includes a reflective diffractive grating.

7. The apparatus of claim 6, wherein the cathode's diffractive grating is capable of scattering a surface plasmon and transverse-magnetic (TM) waveguide modes.

8. The apparatus of claim 1, wherein the diffraction grating is at least partially etched onto the substrate.

9. The apparatus of claim 1, wherein the diffraction grating includes a plurality of gratings.

10. The apparatus of claim 9, wherein the diffraction grating includes a triple grating pattern having a substantially hexagonal characteristic.

11. The apparatus of claim 1, wherein the substrate's diffraction grating includes ridges and valleys and the layer of metal strips is mechanically coupled substantially with the ridges and not the valleys.

12. The apparatus of claim 1, wherein a period of the substrate's diffraction grating is sized to be capable of facilitating the outcoupling of the emitted light.

13. The apparatus of claim 12 wherein the substrate's diffraction grating includes a grating period of between 0.3 microns and 0.6 microns, inclusive.

14. The apparatus of claim 1, wherein the layer of metal strips are 5 nanometers thick.

15. The apparatus of claim 12, wherein the substrate's diffraction grating includes a grating period of between 10 to 20 polariton wavelengths.

16. A system comprising:
a display capable of displaying a user interface, and
including at least one light emitting diode (LED) having:
a substrate having a diffraction grating, wherein the substrate's diffraction grating is capable of at least in part directing the scattering of light emitted by an emissive layer, and
a layer of metal strips disposed substantially along the ridges of the substrate diffraction grating.

17. The system of claim 16, wherein the light emitting diode includes an organic light emitting diode.

18. The system of claim 16, the substrate's diffractive grating includes a transmission diffractive grating.

19. The system of claim 16, further including an anode having a diffraction grating derived, at least in part, from the substrate's diffractive grating and wherein the anode's diffraction grating is capable of at least in part directing the scattering of light emitted by the emissive layer, and
wherein the anode is disposed substantially between the emissive layer and the substrate.

20. The system of claim 19, wherein the anode includes a layer of indium tin oxide (ITO);
wherein the emissive layer includes a layer of Tris-8-Hydroxyquinoline Aluminum (Alq₃);
wherein the layer of metal strips includes silver; and
wherein the substrate includes glass.

21. The system of claim 16, further including a cathode, wherein the emissive layer is disposed substantially between the cathode and the anode, and the cathode includes a reflective diffractive grating.

22. The system of claim 21, wherein the cathode's diffractive grating is capable of scattering a surface plasmon and transverse-magnetic (TM) waveguide modes.

23. The system of claim 16, wherein the diffraction grating is at least partially etched onto the substrate.

24. The system of claim 16, wherein the diffraction grating includes a plurality of gratings.

25. The apparatus of claim 24, wherein the diffraction grating includes a triple grating pattern having a substantially hexagonal characteristic.

26. The system of claim 16, wherein the substrate's diffraction grating includes ridges and valleys and the layer of metal strips is mechanically coupled substantially with the ridges and not the valleys.

27. The system of claim 16, wherein a period of the substrate's diffraction grating is sized to be capable of facilitating the outcoupling of the emitted light.

28. The system of claim 27 wherein the substrate's diffraction grating includes a grating period of between 0.3 microns and 0.6 microns, inclusive.

29. The system of claim 16, wherein the layer of metal strips are 5 nanometers thick.

30. The system of claim 27, wherein the substrate's diffraction grating includes a grating period of between 10 to 20 polariton wavelengths.

31. The system of claim 16, wherein the system includes at least one of a media device and a mobile phone

32. An apparatus comprising:
an emissive means for emitting light,
a diffraction means for directing the scattering of light emitted by the emissive means, and
an outcoupling means for outcoupling of transverse-electric (TE) waveguide modes.

33. The apparatus of claim 32, further comprising means for scattering a surface plasmon and transverse-magnetic (TM) waveguide modes.
